(19) United States
(12) Patent Application Publication
(10) Pub. No.: US 2026/0215214 A1
(43) Pub. Date: Jul. 23, 2026

(54) SENSOR CHECK METHOD AND SUBSTRATE PROCESSING SYSTEM

(71) Applicant: Tokyo Electron Limited, Tokyo (JP)

(72) Inventors: Yoichi KOMATSU, Yamanashi (JP); Daisuke SATO, Iwate (JP)

(21) Appl. No.: 19/454,567

(22) Filed: Jan. 21, 2026

(30) Foreign Application Priority Data
Jan. 23, 2025 (JP) 2025-010018

(51) Int. Cl. H10P 72/00; G01D 5/34

(52) U.S. Cl. CPC H10P 72/0606; G01D 5/342

(57) ABSTRACT

A substrate processing system includes a vacuum transfer module including a vacuum transfer device that transfers a substrate, a position detection sensor that detects a position of the substrate while transferring the substrate by the vacuum transfer device, a transfer device controller that controls an operation of the vacuum transfer device, and a control unit that is communicably connected to the transfer device controller. A sensor check method includes (A) transmitting, from the transfer device controller to the control unit, information on a sensor position recognized by the transfer device controller, (B) determining, by the control unit, whether the position detection sensor is normal or abnormal based on the acquired sensor position, and (C) notifying, when the position detection sensor is determined to be abnormal, information related to an abnormality of the position detection sensor.

### CROSS REFERENCES TO RELATED APPLICATIONS

This application is based on and claims priority from Japanese Patent Application No. 2025-010018, filed on Jan. 23, 2025, with the Japan Patent Office, the disclosure of which is incorporated herein in its entirety by reference.

### TECHNICAL FIELD

The present disclosure relates to a sensor check method and a substrate processing system.

### BACKGROUND

Japanese Patent No. 5600703 discloses a substrate processing system including a vacuum transfer device (e.g., a transfer unit) that transfers a substrate, provided inside a vacuum transfer module (e.g., a transfer chamber). In the substrate processing system, during transfer of the substrate by the vacuum transfer device, the outer edge of the substrate is detected by a position detection sensor installed in the vacuum transfer module to recognize the center position of the substrate, and the transfer operation performed by the vacuum transfer device is corrected. Thus, the substrate processing system may transfer the substrate with high accuracy to a transfer destination module.

### SUMMARY

An aspect of the present disclosure provides a sensor check method of a substrate processing system, the substrate processing system including a vacuum transfer module including a vacuum transfer device that transfers a substrate, a position detection sensor that detects a position of the substrate while transferring the substrate by the vacuum transfer device, a transfer device controller that controls an operation of the vacuum transfer device, and a control unit that is communicably connected to the transfer device controller, the sensor check method including (A) transmitting, from the transfer device controller to the control unit, information on a sensor position recognized by the transfer device controller, (B) determining, by the control unit, whether the position detection sensor is normal or abnormal based on the acquired sensor position, and (C) notifying, when the position detection sensor is determined to be abnormal in (B), information related to abnormality of the position detection sensor.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating a configuration of a substrate processing system according to an embodiment.

FIG. 2 is a diagram schematically illustrating a control unit of the substrate processing system and a transfer device controller of a vacuum transfer device.

FIG. 3A is a side view illustrating detection by a position detection sensor during transfer of a substrate by the vacuum transfer device. FIG. 3B is a plan view illustrating detection of the outer edge of the substrate by the position detection sensor. FIG. 3C is a plan view illustrating calculation of the center position of the substrate.

FIG. 4 is a flowchart illustrating a sensor check method of the position detection sensor in a simplified manner.

FIG. 5 is a table illustrating items of a check processing step of the position detection sensor.

FIG. 6 is a flow chart illustrating a sequence when performing the sensor check method according to teaching of a teaching position.

FIG. 7 is a flowchart illustrating a processing flow of the check processing step by the control unit.

FIG. 8 is a diagram illustrating warning image information.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### Substrate Processing System

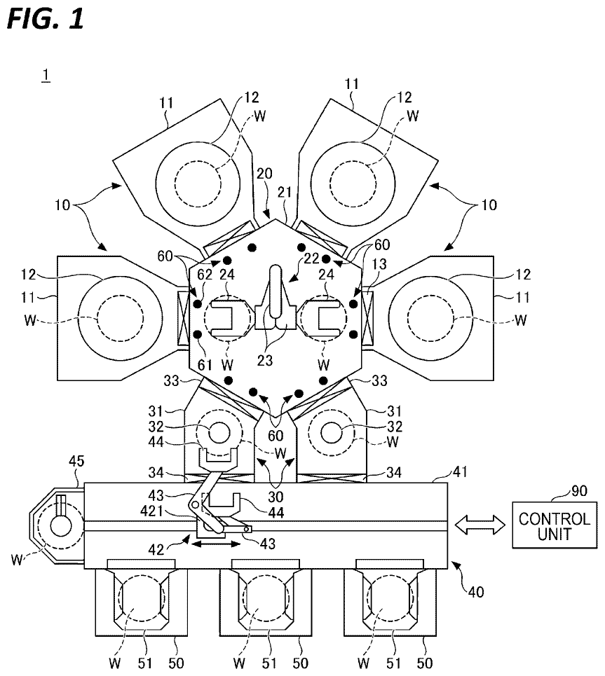

FIG. 1 is a plan view schematically illustrating a configuration of a substrate processing system 1 according to an embodiment. The substrate processing system 1 is configured as a multi-chamber type including a plurality of (e.g., four) processing modules 10 for processing a substrate W. In addition, the substrate processing system 1 is not limited to such a system, and may be, for example, an apparatus that inspects the substrate W, an apparatus that measures a state (such as a film thickness) of the substrate W, and an apparatus that only transfers the substrate W.

Each processing module 10 of the substrate processing system 1 performs a substrate processing, such as film forming processing, etching processing, modification processing, cleaning processing, bonding processing, peeling processing, or ashing processing, on the substrate W transferred to the inside of the module. Further, the substrate processing system 1 includes a vacuum transfer module 20, a plurality of load lock modules 30, an atmospheric transfer module 40, a load port 50, and a control unit 90, in addition to each processing module 10.

Each processing module 10 loads and unloads the substrate W to and from the vacuum transfer module 20, and performs a substrate processing on the loaded substrate W. In addition, needless to say, the number of processing modules 10 provided in the substrate processing system 1 is not particularly limited. Further, the plurality of processing modules 10 may perform the same processing, or some or all of them may perform different processings. The substrate processing system 1 may also be configured to perform a plasma processing in some or all of the processing modules 10.

Each processing module 10 includes a processing container 11 that accommodates the substrate W, and a substrate support 12 that places the substrate W in the inside of the processing container 11. A gate valve 13 is provided at a connection location between the processing container 11 and the vacuum transfer module 20. Each processing module 10 enables transfer of the substrate W to and from the processing container 11 by opening the gate valve 13, and enables the inside of the processing container 11 to be depressurized to an appropriate vacuum atmosphere by closing the gate valve 13. The substrate support 12 includes a lifter (not illustrated) that raises and lowers the substrate W, and cooperates with a vacuum transfer device 22 of the vacuum transfer module 20, which will be described later, to receive and deliver the substrate W.

The vacuum transfer module 20 of the substrate processing system 1 includes a transfer container 21 connected to each processing module 10 and to each load lock module 30, and the vacuum transfer device 22 (transfer device) provided inside the transfer container 21 to transfer the substrate W.

The transfer container 21 is formed into a hexagonal shape in a plan view, and has a transfer space that is airtightly sealed from the outside. The transfer space is depressurized to a vacuum atmosphere by a suction device (not illustrated).

The vacuum transfer device 22 moves inside the transfer space to transfer the substrate W. For example, the vacuum transfer device 22 transfers the substrate W from one load lock module 30 to a target processing module 10. Further, the vacuum transfer device 22 transfers the substrate W from one processing module 10 to a target load lock module 30. Alternatively, the vacuum transfer device 22 may transfer the substrate W between two processing modules 10. In addition, a transfer object transferred by the vacuum transfer device 22 is not limited to the substrate W. For example, when a ring (such as a focus ring or an edge ring), which is a consumable part of the processing module 10, is transferred through the vacuum transfer module 20 to be set in the processing module 10, the ring may be included as a transfer object transferred by the vacuum transfer device 22. The ring is placed around the substrate W on the substrate support 12 of the processing module 10.

The vacuum transfer device 22 includes a base (not illustrated) to which the transfer container 21 is attached, a plurality of arms 23 provided on the top of the base, and a pick 24 provided on the arm 23 at the distal end side. In addition, FIG. 1 illustrates the vacuum transfer device 22 including two picks 24, but the disclosure is not limited thereto, and the vacuum transfer device 22 may include one pick 24 or three or more picks 24.

The base of the vacuum transfer device 22 is fixed, for example, at a central position of the transfer container 21. The base may include a lifting mechanism (not illustrated) that vertically raises and lowers the plurality of arms 23 and the pick 24.

The plurality of arms 23 are connected to one another via a plurality of joints (not illustrated), and one arm is pivotable relative to another arm. Further, the plurality of arms 23 (e.g., the arm 23 at the distal end side) may include an extension/retraction mechanism that enables the arm 23 itself to extend and retract, thereby allowing the pick 24 to advance and retreat. Thus, the base and the plurality of arms 23 may move the pick 24 supported by the arm 23 at the distal end side to a target coordinate (e.g., three-dimensional coordinate or two-dimensional coordinate) position.

Meanwhile, two load lock modules 30 of the substrate processing system 1 are provided between the vacuum transfer module 20 and the atmospheric transfer module 40, and switch the internal pressure thereof between an atmospheric atmosphere and a vacuum atmosphere. Specifically, each load lock module 30 includes a container 31 that accommodates the substrate W, and a substrate support 32 that places the substrate W in the inside of the container 31. For example, the substrate support 32 has a groove (not illustrated) into which the pick 24 of the vacuum transfer device 22, as well as a pick 44 of an atmospheric transfer device 42, which will be described later, may enter, and receives and delivers the substrate W by the advancement/retreat and rising/lowering of the picks 24 and 44.

Further, each load lock module 30 includes a gate valve 33 at the vacuum transfer module 20 side, and a door valve 34 at the atmospheric transfer module 40 side. Each load lock module 30 communicates with the vacuum transfer module 20 by opening the gate valve 33 in a vacuum atmosphere state. Further, each load lock module 30 also communicates with the atmospheric transfer module 40 by opening the door valve 34 in an atmospheric atmosphere state.

The atmospheric transfer module 40 of the substrate processing system 1 maintains the inside thereof in an atmospheric atmosphere while transferring the substrate W. The atmospheric transfer module 40 includes a transfer container 41 connected to each load lock module 30, and the atmospheric transfer device 42 provided inside the transfer container 41 to transfer the substrate W. Further, the atmospheric transfer module 40 includes an aligner 45 at the lateral side to align the position of the substrate W. The atmospheric transfer module 40 may also be configured to downflow clean air to the inside of the transfer container 41.

Furthermore, a plurality of load ports 50 is provided on one side of the atmospheric transfer module 40. A carrier 51 accommodating the substrate W or an empty carrier 51 is set on each load port 50. For example, a Front Opening Unified Pod (FOUP) may be applied as the carrier 51. Further, a carrier 51 accommodating a ring, which is an example of a transfer object, may also be set on each load port 50.

The atmospheric transfer device 42 includes a base 421, which is movable in the longitudinal direction of the transfer container 41, a plurality of arms 43, which are pivotable and extendable/retractable with respect to the base 421, and the pick 44 provided on the arm 43 at the distal end side. The atmospheric transfer device 42 transfers the substrate W by supporting the substrate W on the upper surface of the pick 44 and appropriately operating the base 421 and each arm 43. In addition, FIG. 1 illustrates the atmospheric transfer device 42 including two picks 44, but the disclosure is not limited thereto, and the atmospheric transfer device 42 may include one pick 44 or three or more picks 44.

The atmospheric transfer device 42 loads and unloads the substrate W between each carrier 51 attached to each load port 50 and the atmospheric transfer module 40. Further, the atmospheric transfer device 42 loads and unloads the substrate W between each load lock module 30 and the atmospheric transfer module 40 according to the opening of each door valve 34. Furthermore, the atmospheric transfer device 42 loads and unloads the substrate W to and from the aligner 45 when aligning the substrate W.

Further, the substrate processing system 1 according to the embodiment includes a position detection sensor 60 that detects the position of the substrate W held by the vacuum transfer device 22 when the substrate W is transferred inside the transfer container 21 of the vacuum transfer module 20. The position detection sensor 60 is installed at each of a position adjacent to the gate valve 13 of each processing module 10 and a position adjacent to the gate valve 33 of each load lock module 30. In addition, the position detection sensor 60 may be installed inside the respective gate valves 13 and 33, or may be installed at a position adjacent to an opening inside the processing module 10 or inside the load lock module 30.

Each position detection sensor 60 detects the outer edge of the substrate W when the substrate W is transferred between each processing module 10 and the vacuum transfer module 20 (or when the substrate W is transferred between each load lock module 30 and the vacuum transfer module 20). Detection information, including the timing at which the position detection sensor 60 detects the substrate W, is transmitted to the control unit 90 and to a transfer device controller 25 to be described later. The transfer device controller 25 may calculate the center position of the substrate W transferred by the vacuum transfer device 22 in each module (e.g., each processing module 10 or each load lock module 30) based on the detection information of each position detection sensor 60. The transfer device controller 25 may recognize the current state of positional deviation (positional deviation direction and positional deviation amount) of the substrate W by comparing the center position of the substrate W with a teaching position stored in advance by teaching.

The position detection sensor 60 includes a detector 61 located on the left side and a detector 62 located on the right side as viewed from the vacuum transfer device 22. For example, each of the detectors 61 and 62 has a light emitting element that emits measurement light and a light receiving element that receives the light from the light emitting element across a path through which the substrate W passes. Each of the detectors 61 and 62 detects the outer edge of the substrate W at each timing at which the measurement light is blocked or released based on the passage of the substrate W. Each of the detectors 61 and 62 is arranged in a direction parallel to an opening 11a and is positioned such that the interval between them is shorter than the diameter of the substrate W. The left detector 61 and the right detector 62 are configured to output different detection values, for example, so that there is a difference between their detection information. The principle by which the position detection sensor 60 detects the position of the substrate W will be described later in detail.

The control unit 90 of the substrate processing system 1 controls each component to perform the transfer and processing of the substrate W. For example, the control unit 90 controls the atmospheric transfer module 40 to transfer an unprocessed substrate W accommodated in the carrier 51 set on the load port 50 to the aligner 45 for alignment, and further transfers the aligned substrate W from the aligner 45 to each load lock module 30. After performing depressurization in the load lock module 30, the control unit 90 controls the vacuum transfer module 20 to take out the substrate W by the vacuum transfer device 22 and to load the substrate W into a target processing module 10. Thereafter, the control unit 90 controls the processing module 10 to perform a substrate processing on the loaded substrate W. After the substrate processing, the control unit 90 controls various components to transfer the processed substrate W from the processing module 10 to the carrier 51 in the reverse order of the above.

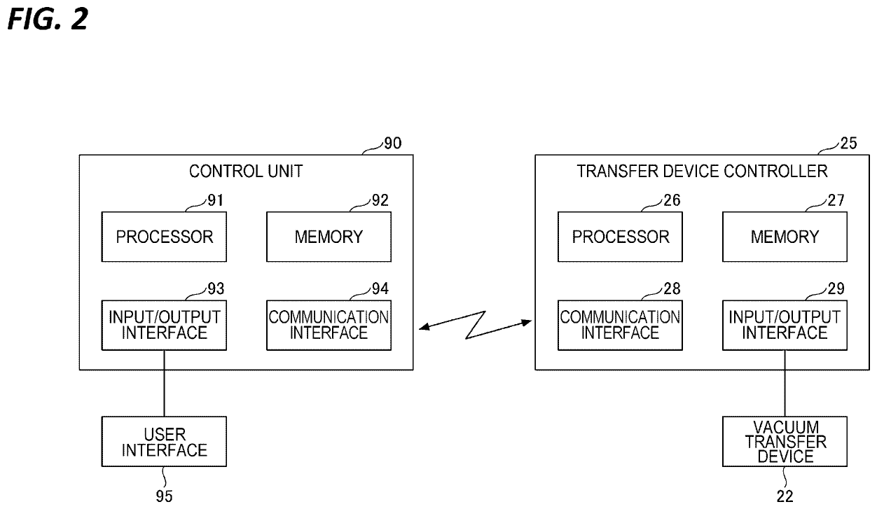

FIG. 2 is a diagram schematically illustrating the control unit 90 of the substrate processing system 1 and the transfer device controller 25 of the vacuum transfer device 22. As illustrated in FIG. 2, when operating the vacuum transfer device 22, the control unit 90 transmits a command to the transfer device controller 25 of the vacuum transfer device 22. For example, the command includes information such as a module serving as a transfer source of the substrate W, a module serving as a transfer destination of the substrate W, and a transfer timing. The transfer device controller 25 controls the operation of the base or each arm 23 of the vacuum transfer device 22 based on the received command. Further, the transfer device controller 25 stores a teaching position taught in advance for the transfer of the substrate W. When receiving a control command, the transfer device controller 25 reads out a teaching position of a transfer source and a teaching position of a transfer destination, and operates the vacuum transfer device 22 based on the respective teaching positions.

The control unit 90 is a computer including a processor 91, a memory 92, an input/output interface 93, and a communication interface 94. The processor 91 is formed by combining one or more of a Central Processing Unit (CPU), Graphics Processing Unit (GPU), Application Specific Integrated Circuit (ASIC), Field-Programmable Gate Array (FPGA), a circuit including a plurality of discrete semiconductor devices, and others. The memory 92 includes a main storage device including a semiconductor memory and others, and an auxiliary storage device including a disk, semiconductor memory (flash memory), and others. The memory 92 may be configured by appropriately combining a volatile memory and a non-volatile memory (e.g., a compact disk, Digital Versatile Disc (DVD), hard disk, and flash memory).

The memory 92 stores programs to operate the substrate processing system 1 and recipes including process conditions for substrate processing. The processor 91 controls each component of the substrate processing system 1 by reading out and executing the programs stored in the memory 92. For example, the control unit 90 is an electronic circuit having a CPU, a GPU, an ASIC, an FPGA, and others, and executes various control operations described in this specification by executing instruction codes stored in the memory 92 or by being circuit-designed for special purposes. In addition, the control unit 90 may be configured by a host computer or a plurality of client computers that communicate information via a network.

Further, a user interface 95 is connected to the control unit 90 via the input/output interface 93. The user interface 95 is, for example, a monitor, a speaker, a keyboard, a mouse, a touch panel, or others, and is configured to allow a user of the substrate processing system 1 to recognize information and to input information.

Furthermore, the control unit 90 is configured to perform information communication with various devices including the transfer device controller 25 via the communication interface 94. The communication between the control unit 90 and various devices may be either wired communication or wireless communication.

The transfer device controller 25 is a dedicated control device of the vacuum transfer device 22, and is configured by a control board (computer) having a processor 26, a memory 27, a communication interface 28, and an input/output interface 29. The processor 26 is configured, similarly to the processor 91, using a CPU, a GPU, an ASIC, an FPGA, a circuit including a plurality of discrete semiconductor devices, or others. The memory 27 also includes a main storage device and an auxiliary storage device, similarly to the memory 92.

The transfer device controller 25 outputs a signal to a drive driver of each drive (such as a lifting mechanism, each joint, and an extension/retraction mechanism) of the vacuum transfer device 22 via the input/output interface 28, thereby operating each drive. Further, the transfer device controller 25 also receives information including a control command from the control unit 90 via the communication interface 29, and transmits appropriate information to the control unit 90.

The vacuum transfer device 22 and the atmospheric transfer device 42 described above perform a teaching method for teaching a teaching position for transferring the substrate W to a transfer destination at the time of installation of the device, replacement of parts, or other maintenance. For example, a transfer destination of the vacuum transfer device 22 is the substrate support 12 of each processing module 10 and the substrate support 32 of each load lock module 30.

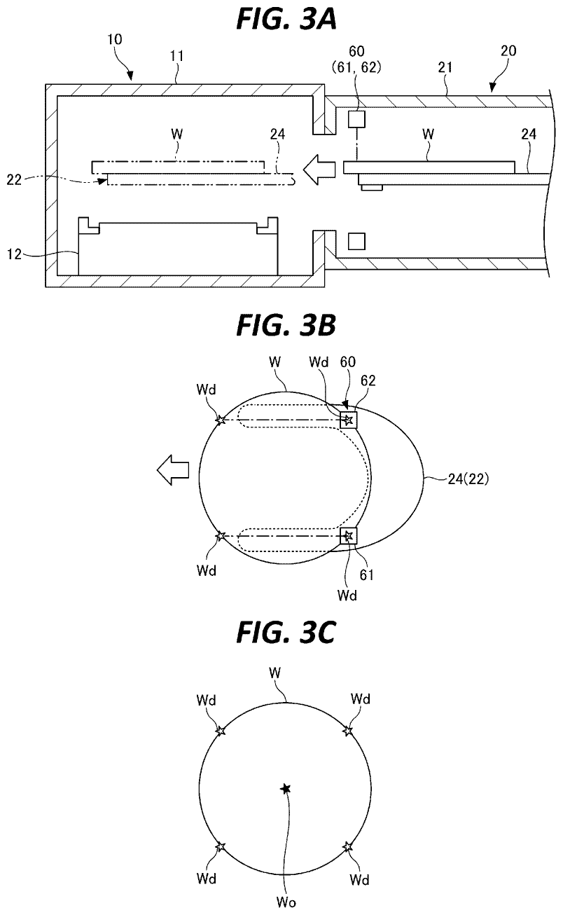

FIG. 3A is a side view illustrating detection by the position detection sensor 60 during transfer of the substrate W by the vacuum transfer device 22. FIG. 3B is a plan view illustrating detection of the outer edge of the substrate W by the position detection sensor 60. FIG. 3C is a plan view illustrating calculation of the center position of the substrate W. In the teaching method by the vacuum transfer device 22, for example, the user places the substrate W by using a jig or a similar one to match the center position Wo of the substrate W with the center of each pick 24 of the vacuum transfer device 22. Then, the substrate processing system 1 controls the operation of the vacuum transfer device 22 by the transfer device controller 25.

As illustrated in FIG. 3A, the transfer device controller 25 controls the vacuum transfer device 22 to transfer the substrate W to the processing module 10, which is an example of a transfer destination. The vacuum transfer device 22 sets the substrate support 12 of the processing module 10, which is designed in advance, as a target transfer destination position, and transfers the substrate W toward the substrate support 12. When loading the substrate W into the processing module 10 as a transfer destination, the vacuum transfer device 22 extends the arm 23 at the distal end side, thereby advancing the pick 24 and the substrate W horizontally and linearly. At this time, the transfer device controller 25 recognizes the position (e.g., three-dimensional coordinates) of the pick 24 holding the substrate W while operating each arm 23 of the vacuum transfer device 22.

Meanwhile, as illustrated in FIG. 3B, the position detection sensor 60 located near the processing module 10 detects four locations Wd on the outer edge of the substrate W by scanning the sliding substrate W with the respective detectors 61 and 62. Accordingly, the transfer device controller 25 acquires detection information from the position detection sensor 60 and associates detection timings at the respective detectors 61 and 62 with the recognized position of the pick 24, thereby enabling recognition of coordinates of the four locations Wd on the outer edge of the substrate W (see, e.g., white stars in FIG. 3B).

Then, the transfer device controller 25 calculates the center position Wo of the substrate W (see, e.g., a black star in FIG. 3C) by using the coordinates of the four detected locations Wd. The center position Wo of the substrate W corresponds to the center position of the pick 24 holding the substrate W. For example, the transfer device controller 25 may calculate normal lines directed radially inward from the four detected locations (Wd), respectively, and may calculate a location where the normal lines intersect with each other as the center position Wo of the substrate W. Thus, the transfer device controller 25 may recognize the position of the pick 24 (e.g., the center position Wo of the substrate W) passing through the position detection sensor 60 when transferring the substrate W to the substrate support 12 of the processing module 10.

Further, the transfer device controller 25 may recognize an installation position of the left detector 61 (e.g., a left sensor position) in the vacuum transfer module 20 based on at least one of positions of two locations Wd detected by the left detector 61. Likewise, the transfer device controller 25 may recognize an installation position of the right detector 62 (e.g., a right sensor position) in the vacuum transfer module 20 based on at least one of positions of two locations Wd detected by the right detector 62.

The transfer device controller 25 acquires a teaching position for each module required when the vacuum transfer device 22 transfers the substrate W by performing the above-described teaching method for each processing module 10 and each load lock module 30. In addition, the teaching method is not limited to the above description, and may be configured, for example, such that the position detection sensor 60 detects the pick 24 that does not hold the substrate W, thereby calculating a teaching position of the pick 24 for each module. As an example, the detectors 61 and 62 of the position detection sensor 60 may detect each of a pair of claws bifurcating from the pick 24.

In the meantime, the teaching position acquired by teaching by the vacuum transfer device 22 described above presupposes that each position detection sensor 60 installed in the substrate processing system 1 is capable of detecting a target object at an accurate sensor position. However, when the position detection sensor 60 is attached in a displaced or tilted manner, when the left detector 61 and the right detector 62 are attached in reverse, or when the position detection sensor 60 itself has abnormality, detection information of the position detection sensor 60 will not be accurate. Further, the position detection sensor 60 has a possibility that the light intensity of the sensor may decrease due to aging variation or adhesion of foreign substances during operation. Therefore, in the substrate processing system 1 according to the embodiment, the position detection sensor 60 is also configured to be checked.

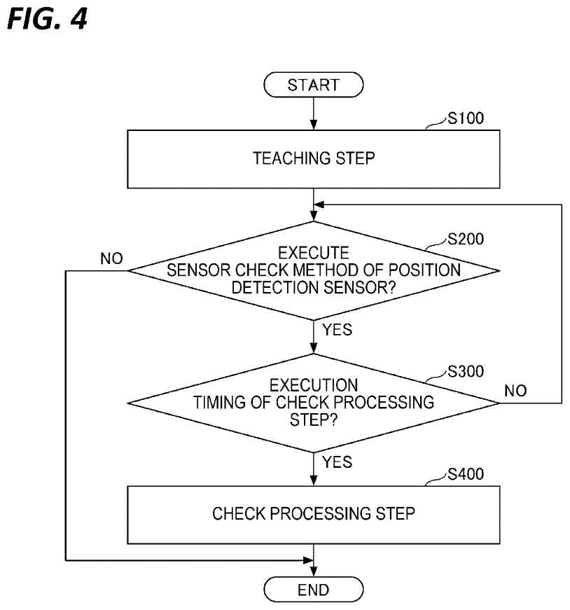

FIG. 4 is a flowchart illustrating a sensor check method of the position detection sensor 60 in a simplified manner. In the sensor check method, the control unit 90 of the substrate processing system 1 executes a processing flow of steps S100 to S400, as illustrated in FIG. 4.

Specifically, the control unit 90 first performs a teaching step by the vacuum transfer device 22, causing the position detection sensor 60 to execute detection (step S100). In the teaching step, as described above, the vacuum transfer device 22 is operated to allow the position detection sensor 60 to detect the substrate W (or the pick 24). Thus, the transfer device controller 25 recognizes a teaching position during transfer of the vacuum transfer device 22, and also recognizes sensor positions (e.g., a left sensor position and a right sensor position).

After the teaching step, the control unit 90 determines whether to perform a check of each position detection sensor 60 (step S200). Here, in the substrate processing system 1, whether a check of each position detection sensor 60 is to be performed may be selected in advance by the user via the user interface 95. Therefore, the control unit 90 determines whether to perform a check of each position detection sensor 60 based on the user's selection result. Then, when the check is not to be performed (step S200: NO), the processing flow of the sensor check method ends. In the meantime, when the check is to be performed, the processing flow proceeds to step S300.

In step S300, the control unit 90 monitors the timing for performing a check processing step of the position detection sensor 60, and determines whether the timing for the check processing step has been reached. As the timing for the check processing step, for example, immediately after performing the teaching step by the vacuum transfer device 22, or after restarting and initializing the vacuum transfer device 22 during maintenance of the vacuum transfer module 20 or software version upgrade may be cited. When the timing for performing the check processing step has not been reached (step S300: NO), the processing flow returns to step S200 to repeat the same processing flow. In the meantime, when the timing for performing the check processing step has been reached (step S300: YES), the processing flow proceeds to step S400.

Then, in step S400, the control unit 90 executes a check processing step of each position detection sensor 60. In the check processing step, the control unit 90 acquires information stored in the transfer device controller 25, thereby checking normality or abnormality of each position detection sensor 60 on the control unit 90 side.

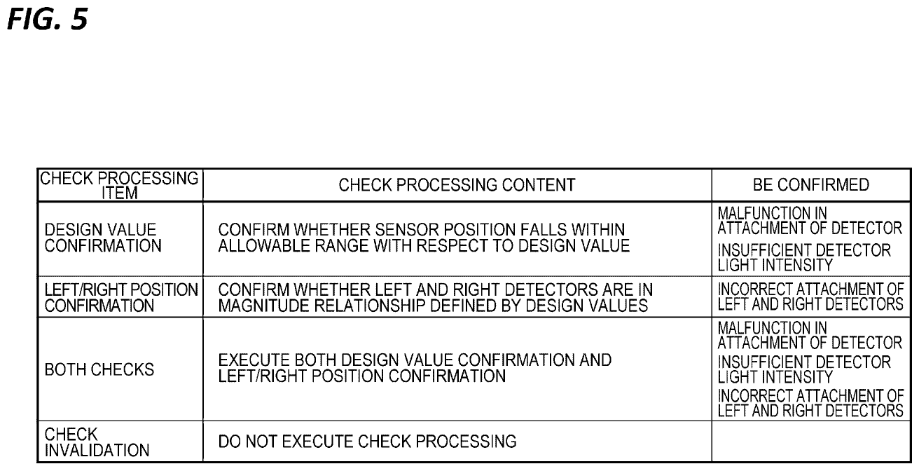

FIG. 5 is a table illustrating items of the check processing step of the position detection sensor 60. In the check processing step of the position detection sensor 60, the validity of the left sensor position and the right sensor position is confirmed for each module. Examples of processing contents of the check processing step may include “design value confirmation” and “left/right position confirmation” as illustrated in FIG. 5.

The “design value confirmation” is a process of determining whether the left sensor position and right sensor position recognized by the vacuum transfer device 22 (transfer device controller 25) fall within an allowable range with respect to a design value serving as a criterion. When the left sensor position or the right sensor position is outside the allowable range, there is a possibility that a malfunction has occurred in the installation of the detectors 61 and 62, or that abnormality has occurred in the detectors 61 and 62 themselves. The design value is a predefined value for the installation of the position detection sensor 60 to the vacuum transfer module 20, and the manufacturer installs the position detection sensor 60 based on the design value. For example, the design value is a numerical value representing two-dimensional coordinates of the position detection sensor 60 in each processing module 10 and in each load lock module 30 with respect to the vacuum transfer device 22 of the vacuum transfer module 20.

More specifically, the design value includes a coordinate in the R direction that is the advancing and retreating direction of the pick 24 (e.g., Y direction with the installation position of the vacuum transfer device 22 as the zero point), and a coordinate in the T direction that is the pivoting direction of the pick 24 (e.g., X direction with the installation position of the vacuum transfer device 22 as the zero point). In the design value confirmation, it is confirmed whether the coordinate in the R direction falls within an allowable range, and it is also confirmed whether the coordinate in the T direction falls within an allowable range. That is, in the design value confirmation, the control unit 90 determines whether the following equations (1) and (2) are satisfied for each of the left detector 61 and the right detector 62.

(RP0−Rα)≤RS≤(RP0 Rα) (1)

(TP0−Tβ)≤TS≤(TP0+Tβ) (2)

Here, RP0 is the design value in the R direction, Rα is the value within the allowable range in the R direction, and RS is the sensor position in the R direction acquired from the vacuum transfer device 22. Further, TP0 is the design value in the T direction, Tβ is the value within the allowable range value in the T direction, and TS is the sensor position in the T direction acquired from the vacuum transfer device 22. The values within the allowable ranges Rα and Tβ may be the same value, or may be different values. Further, Rα and Tβ may be parameters that may be set by the user of the substrate processing system 1, or may be parameters that are set automatically.

Meanwhile, the “left/right position confirmation” in the check processing step is a process of recognizing the attachment state of the detectors 61 and 62 by comparing the left and right sensor positions acquired from the transfer device controller 25 and confirming whether a correct magnitude relationship is satisfied. Here, the vacuum transfer module 20 sets different magnitude relationships between the positions of the left detector 61 and the right detector 62 in the attachment of the position detection sensor 60 to the vacuum transfer module 20. Accordingly, when the left detector 61 and the right detector 62 are incorrectly attached, a correct magnitude relationship will not be satisfied.

In the left/right position confirmation, the control unit 90 compares a magnitude relationship between the acquired left sensor position and the right sensor position in each of the R direction and the T direction, thereby confirming whether the left and right detectors 61 and 62 are in a magnitude relationship defined by the design values. When the magnitude relationship is reversed, it may be recognized that the left detector 61 and the right detector 62 are attached in reverse positions.

Further, the check processing step may adopt “both checks” in which both the “design value confirmation” and the “left/right position confirmation” described above are performed. Alternatively, “check invalidation” in which neither the “design value confirmation” nor the “left/right position confirmation” is performed, i.e., the check processing step is not executed, may be adopted. That is, the control unit 90 executes the check processing step depending on selected contents when the user selects one of the “design value confirmation,” the “left/right position confirmation,” or the “both checks” on a setting screen for the sensor check method via the user interface 95. Conversely, the control unit 90 sets the check processing step to non-execution when the “check invalidation” is selected by the user.

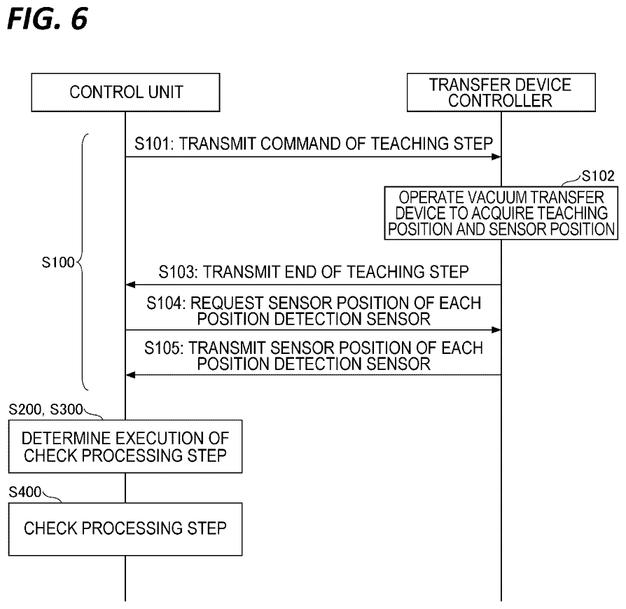

The substrate processing system 1 according to the embodiment is basically configured as described above, and the processing flow of the sensor check method will be further described in detail below. In addition, in the following description, an example is given in which the sensor check method is performed immediately after teaching of a teaching position by the vacuum transfer device 22. FIG. 6 is a flow chart illustrating a sequence when performing the sensor check method according to teaching of a teaching position.

As illustrated in FIG. 6, the substrate processing system 1 performs information communication between the control unit 90 and the transfer device controller 25 in the sensor check method including teaching by the vacuum transfer device 22. Specifically, when the teaching step (step S100) illustrated in FIG. 4 starts, the control unit 90 first transmits a command to the transfer device controller 25 to perform teaching by the vacuum transfer device 22 (step S101).

The transfer device controller 25 operates the vacuum transfer device 22 to perform teaching based on the command from the control unit 90, thereby acquiring a teaching position and a sensor position (step S102). As described above, the transfer device controller 25 stores, in the memory 27, the teaching position and sensor position depending on detection by each position detection sensor 60 for each module, and repeats teaching at each position detection sensor 60 of all modules, thereby performing teaching of all of the modules.

Then, the transfer device controller 25 transmits, to the control unit 90, information indicating that teaching by the vacuum transfer device 22 has been completed (step S103).

When the control unit 90 acquires information indicating completion of teaching, the control unit 90 transmits, to the transfer device controller 25, a command requesting the sensor position of each position detection sensor 60 (step S104).

Upon receiving this command, the transfer device controller 25 transmits, to the control unit 90, information on the sensor position of each module acquired in teaching by the vacuum transfer device 22 (step S105). Through the above processing flow, the teaching step (step S100) is completed. Thereafter, the substrate processing system 1 may perform a step of determining whether to execute the check processing step (steps S200 and S300) and the check processing step (step S400) in the control unit 90.

In addition, the transfer device controller 25 and the control unit 90 may be configured to transmit the sensor position, the teaching position, and others of each position detection sensor 60 together when transmitting information indicating completion of teaching (step S103). This allows steps S104 and S105 to be omitted. Further, when confirming the validity of the sensor position of the position detection sensor 60 after restarting and initializing the vacuum transfer device 22, the substrate processing system 1 may omit steps S101 to S103 and perform only the inquiry of the sensor position in steps S104 and S105. This is because, after restart, information on the sensor position and the teaching position of the vacuum transfer device 22 is not updated, and the transfer device controller 25 stores the sensor position information.

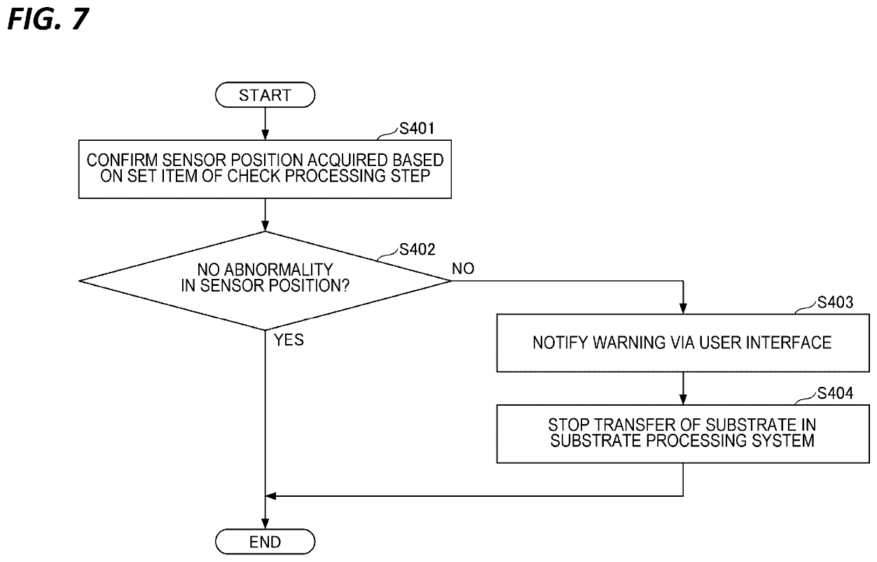

FIG. 7 is a flowchart illustrating a processing flow of the check processing step of the control unit 90. When the check processing step (step S400) starts, the control unit 90 checks the validity of the acquired sensor position based on designated items of the check processing step (“design value confirmation,” “left/right position confirmation,” and “both checks”) illustrated in FIG. 5 (step S401). At this time, the control unit 90 confirms the sensor position of the detectors 61 and 62 of the position detection sensor 60 for each module, and stores information on the confirmation results (information on normality or abnormality of the sensor position) in the memory 27.

When the confirmation of the sensor position for all modules is completed, the control unit 90 determines whether no abnormality is present in the sensor position based on the information on the confirmation results (step S402). When no abnormality is present in the sensor position (step S402: YES), detection of all position detection sensors 60 in the respective modules are regarded as reliable. Therefore, the control unit 90 ends the sensor check method currently being performed. In the meantime, when abnormality is present in at least one sensor position in the respective modules (step S402: NO), the processing flow proceeds to step S403.

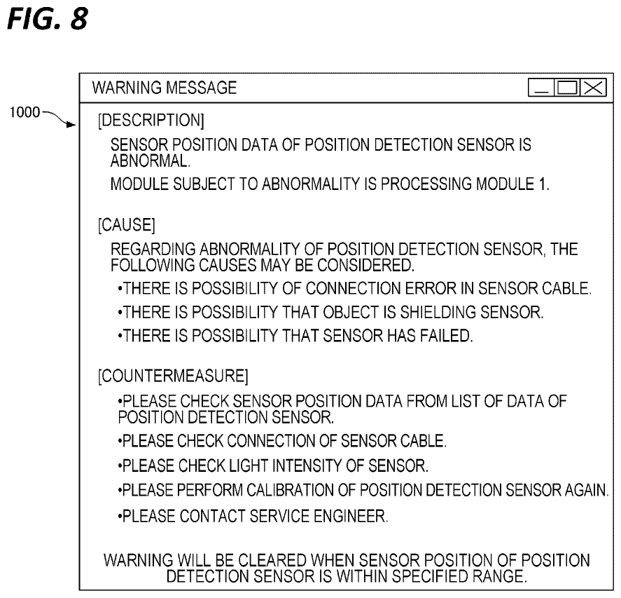

In step S403, the control unit 90 notifies the user, via the user interface 95, of a warning that abnormality is present in the detection of the position detection sensor 60. As an example of such a warning, warning image information 1000 as illustrated in FIG. 8 may be displayed on a monitor of the user interface 95. FIG. 8 is a diagram illustrating the warning image information 1000.

For example, the warning image information 1000 is information that notifies the user of abnormality in the sensor position of the position detection sensor 60 in the vacuum transfer module 20, and allows the user to recognize the module (in FIG. 8, one of the processing modules 10) in which abnormality is occurring. Further, the warning image information 1000 may additionally display the cause of abnormality of the position detection sensor 60. Furthermore, it is desirable that the warning image information 1000 additionally display countermeasures for abnormality of the position detection sensor 60. Thus, the user who views the warning image information 1000 may promptly recognize abnormality of the position detection sensor 60.

Referring back to FIG. 7, the control unit 90, together with issuing the warning in step S403, executes an interlock to stop the transfer of the substrate W in the substrate processing system 1 (step S404). This allows the substrate processing system 1 to stop the transfer of the substrate W when the detection of the position detection sensor 60 is unreliable. As a result, the substrate processing system 1 may prevent, in advance, troubles such as placing the substrate W in a module in a state where a positional deviation of the substrate W has occurred.

Further, the control unit 90 performs a processing for discarding a teaching position calculated in teaching by the vacuum transfer device 22 with respect to the position detection sensor 60 for which abnormality has been recognized. This is because the teaching position based on the detection of the position detection sensor 60 for which abnormality has been recognized may have a possibility that a positional deviation is occurring. In this case, the substrate processing system 1 may automatically perform again the teaching step (step S100) by the vacuum transfer device 22 for that module after reattachment, replacement, or other maintenance of the position detection sensor 60, thereby acquiring a new teaching position.

As described above, the sensor check method and the substrate processing system 1 may sufficiently check the state of the position detection sensor 60, thereby ensuring the reliability of the sensor. Therefore, the substrate processing system 1 may perform teaching by the vacuum transfer device 22 with high accuracy, and during operation, the substrate processing system 1 may transfer the substrate W with high accuracy by using the vacuum transfer device 22.

In addition, the sensor check method and the substrate processing system 1 are not limited to the above-described embodiment, and may take various modifications. For example, the number of detectors 61 and 62 of the position detection sensor 60 is not particularly limited, and three or more detectors may be provided. Further, the sensor check method may be configured such that, for example, when an accumulated period exceeds a predetermined period during the operation process of the substrate processing system 1 that performs a substrate processing, the teaching step (step S100) is included and executed. Thus, the sensor check method and the substrate processing system 1 may ensure recognition of abnormality based on the aging variation of the position detection sensor 60 during the operation process.

Alternatively, when the substrate processing system 1 recognizes abnormality in any of the position detection sensors 60 adjacent to the respective processing modules 10 and the respective load lock modules 30, the substrate processing system 1 may regulate only the transfer of the substrate W to the module for which abnormality has been recognized, without stopping the entire system. Thus, the substrate processing system 1 may continue operation until maintenance is performed, and may perform the transfer and processing of the substrate W using the modules in which the position detection sensors 60 are normal.

### Supplementary

The technical ideas and effects of the present disclosure described in the above embodiment will be described below.

A first aspect of the present disclosure is a sensor check method of a substrate processing system 1, the substrate processing system 1 including a vacuum transfer module 20 including a vacuum transfer device 22 that transfers a substrate W, a position detection sensor 60 that detects a position of the substrate W while transferring the substrate W by the vacuum transfer device 22, a transfer device controller 25 that controls an operation of the vacuum transfer device 22, and a control unit 90 that is communicably connected to the transfer device controller 25, the sensor check method including (A) transmitting, from the transfer device controller 25 to the control unit 90, information on a sensor position recognized by the transfer device controller 25, (B) determining, by the control unit 90, whether the position detection sensor 60 is normal or abnormal based on the acquired sensor position, and (C) notifying, when the position detection sensor 60 is determined to be abnormal in (B), information related to abnormality of the position detection sensor 60.

According to the above, the sensor check method may satisfactorily determine, by the control unit 90, normality or abnormality of the position detection sensor 60 by using the sensor position information acquired by the transfer device controller 25. Then, when abnormality has occurred in the position detection sensor 60, information related to the abnormality is notified to the user, so that the user may take an appropriate countermeasure. As a result, the substrate processing system 1 may prevent troubles caused by abnormality of the position detection sensor 60 in advance.

Further, the control unit 90 stores a design value of the position detection sensor 60 and an allowable range with respect to the design value, and in (B), the control unit 90 determines that the position detection sensor 60 is normal when the sensor position falls within the allowable range, while determining that the position detection sensor 60 is abnormal when the sensor position falls outside the allowable range. Thus, the control unit 90 may easily and reliably determine a deviation of detection of the position detection sensor 60 with respect to the design value.

Further, the position detection sensor 60 includes a plurality of detectors 61 and 62 that detect an outer edge of the substrate W, and in (B), the control unit 90 determines whether an attachment state of the plurality of detectors 61 and 62 is normal or abnormal by comparing a magnitude relationship of the plurality of detectors 61 and 62 stored in advance with a magnitude relationship of the plurality of detectors 61 and 62 as acquired. Thus, the substrate processing system 1 may easily and reliably determine whether the plurality of detectors 61 and 62 have been incorrectly attached.

Further, the vacuum transfer module 20 is connected to a plurality of processing modules 10 that process the substrate W and to a load lock module 30 that switches pressure between a vacuum atmosphere and an atmospheric atmosphere, the position detection sensor 60 is provided at a position adjacent to each of the plurality of processing modules 10 and the load lock module 30, and in (B), the control unit 90 determines whether each of a plurality of position detection sensors 60 is normal or abnormal. Thus, the substrate processing system 1 may determine normality or abnormality of the position detection sensor 60 of all modules connected to the vacuum transfer module 20, and may stably perform the transfer of the substrate W in the vacuum transfer module 20.

Further, before (A), the transfer device controller 25 operates the vacuum transfer device 22 to calculate a teaching position of the vacuum transfer device 22 based on detection information detected by the position detection sensor 60 during operation, and then to calculate the sensor position of the position detection sensor 60. Thus, the transfer device controller 25 may satisfactorily acquire the teaching position of the vacuum transfer device 22, and the substrate processing system 1 may recognize normality or abnormality of the position detection sensor 60 based on the sensor position obtained in this teaching.

Further, in (C), the calculated teaching position of the vacuum transfer device 22 is discarded. Thus, the substrate processing system 1 may avoid using a teaching position for which abnormality have occurred in the position detection sensor 60, thereby enabling stable transfer of the substrate W.

Further, in (C), warning image information is displayed via a user interface 95 of the control unit 90. Thus, the user of the substrate processing system 1 may easily recognize abnormality of the position detection sensor 60.

Further, in (C), transfer of the substrate W by the vacuum transfer device 22 is stopped. Thus, the substrate processing system 1 may reliably prevent the transfer of the substrate W in a state where abnormality is present in the position detection sensor 60.

Further, a second embodiment of the present disclosure is a substrate processing system 1 including a vacuum transfer module 20 including a vacuum transfer device 22 that transfers a substrate W, a position detection sensor 60 that detects a position of the substrate W during transfer of the substrate W by the vacuum transfer device 22, a transfer device controller 25 that controls an operation of the vacuum transfer device 22, and a control unit 90 that is communicably connected to the transfer device controller 22, wherein the control unit controls a process including (A) acquiring, from the transfer device controller 25, information on a sensor position recognized by the transfer device controller 25, (B) determining whether the position detection sensor 60 is normal or abnormal based on the acquired sensor position, and (C) notifying, when the position detection sensor 60 is determined to be abnormal in (B), information related to abnormality of the position detection sensor 60. Even in this case, the substrate processing system 1 may prevent troubles caused by abnormality in the position detection sensor from occurring in advance.

According to one aspect, troubles caused by abnormality of a position detection sensor may be prevented in advance.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A sensor check method comprising:
providing a substrate processing system including:
a vacuum transfer module including a vacuum transfer device configured to transfer a substrate;
a position detection sensor configured to detect a position of the substrate while transferring the substrate by the vacuum transfer device;
a transfer device controller configured to control an operation of the vacuum transfer device; and
a controller communicably connected to the transfer device controller;
transmitting, from the transfer device controller to the controller, information on a sensor position recognized by the transfer device controller;
determining, by the controller, whether the position detection sensor is normal or abnormal based on the sensor position received from the transfer device controller; and
notifying, when the position detection sensor is determined to be abnormal, information related to an abnormality of the position detection sensor.

2. The sensor check method according to claim 1, wherein the controller stores a design value of the position detection sensor and an allowable range with respect to the design value, and
in the determining, the controller determines that the position detection sensor is normal when the sensor position falls within the allowable range, while determining that the position detection sensor is abnormal when the sensor position falls outside the allowable range.

3. The sensor check method according to claim 1, wherein the position detection sensor includes a plurality of detectors configured to detect an outer edge of the substrate, and
wherein in the determining, the controller determines whether an attachment state of the plurality of detectors is normal or abnormal by comparing a magnitude relationship of the plurality of detectors stored in advance with a magnitude relationship of the plurality of detectors received from the transfer device controller.

4. The sensor check method according to claim 1, wherein the vacuum transfer module is connected to a plurality of processing modules configured to process the substrate and to a load lock module configured to switch pressure between a vacuum atmosphere and an atmospheric atmosphere,
the position detection sensor is provided at a position adjacent to each of the plurality of processing modules and the load lock module, and
in the determining, the controller determines whether each of a plurality o position detection sensors is normal or abnormal.

5. The sensor check method according to claim 1, wherein, before the transmitting, the transfer device controller operates the vacuum transfer device to calculate a teaching position of the vacuum transfer device based on detection information detected by the position detection sensor during operation, and to calculate the sensor position of the position detection sensor.

6. The sensor check method according to claim 5, wherein in the notifying, the calculated teaching position of the vacuum transfer device is discarded.

7. The sensor check method according to claim 1, wherein in the notifying, warning image information is displayed via a user interface of the controller.

8. The sensor check method according to claim 1, wherein in the notifying, transfer of the substrate by the vacuum transfer device is stopped.

9. A substrate processing system comprising:
a vacuum transfer module including a vacuum transfer device configured transfer a substrate;
a position detection sensor configured to detect a position of the substrate while transferring the substrate by the vacuum transfer device;
a transfer device controller configured to control an operation of the vacuum transfer device; and
a controller communicably connected to the transfer device controller,
wherein the controller controls a process including:
acquiring, from the transfer device controller, information on a sensor position recognized by the transfer device controller;
determining whether the position detection sensor is normal or abnormal based on the acquired sensor position; and
notifying, when the position detection sensor is determined to be abnormal, information related to an abnormality of the position detection sensor.
